(19) United States
(12) Patent Application Publication
(10) Pub. No.: US 2015/0155424 A1
(43) Pub. Date: Jun. 4, 2015

(54) PHOTOVOLTAIC DEVICE

(71) Applicant: FIRST SOLAR, INC., Perrysburg, OH (US)

(72) Inventors: Arnold Allenic, San Jose, CA (US); Viral Parikh, Perrysburg, OH (US); Rick C. Powell, Ann Arbor, MI (US); Gang Xiong, Santa Clara, CA (US)

(21) Appl. No.: 14/617,201

(22) Filed: Feb. 9, 2015

Related U.S. Application Data
(62) Division of application No. 13/328,638, filed on Dec. 16, 2011.
(60) Provisional application No. 61/424,492, filed on Dec. 17, 2010.

(51) Int. Cl. H01L 31/18; H01L 31/0224

(52) U.S. Cl. CPC H01L 31/1836; H01L 31/022466; H01L 31/022441

(57) ABSTRACT

In general, a photovoltaic module may include a binary semiconductor layer formed from a vapor rich in one component of a binary semiconductor source.

### CLAIM OF PRIORITY

This application is a divisional of Application No. 13/328,638, filed Dec. 16, 2011, which claims priority under 35 U.S.C. §119(e) to U.S. Provisional Patent Application Ser. No. 61/424,492 filed on Dec. 17, 2010, which are hereby incorporated by reference in their entirety.

### TECHNICAL FIELD

The present invention relates to photovoltaic devices and methods of production.

### BACKGROUND

A photovoltaic device can include semiconductor material deposited over a substrate, for example, with a first layer serving as a window layer and a second layer serving as an absorber layer. The layers of semiconductor material can include an n-type semiconductor window layer, and a p-type semiconductor absorber layer. Past photovoltaic devices have been lacking in efficiency, versatility, robustness, and many other areas.

### DESCRIPTION OF DRAWINGS

FIG. 1 is a schematic of a photovoltaic module having multiple layers.

FIG. 2 is a schematic of a photovoltaic module having multiple layers.

### DETAILED DESCRIPTION

Photovoltaic devices can include multiple layers formed on a substrate (or superstrate). For example, a photovoltaic device can include a barrier layer, a transparent conductive oxide (TCO) layer, a buffer layer, and a semiconductor layer, created (e.g., formed or deposited) adjacent to a substrate. Each layer may include more than one layer or film. For example, the semiconductor layer can include either one or both of a semiconductor window layer adjacent to the transparent conductive oxide layer and a semiconductor absorber layer adjacent to the semiconductor window layer. Photons pass through the semiconductor window layer and are absorbed by the semiconductor absorber layer to generate electrical power. Each layer can cover all or a portion of the device and/or all or a portion of the layer or substrate underlying the layer. For example, a “layer” can mean any amount of any material that contacts all or a portion of a surface. In general, a semiconductor layer such as a semiconductor absorber layer can be formed by forming a vapor comprising a first and second component (e.g., cadmium and tellurium), where the vapor is rich in one of the components (e.g., cadmium-rich or tellurium-rich) and depositing the vapor on a substrate to form the semiconductor absorber layer.

Crystal quality and crystal growth plays an important role in the performance of semiconductor devices. The orientation and crystal growth of cadmium telluride films can be modified by altering the stoichiometry of the cadmium telluride powder used in vapor transport deposition processes. For example, a substantially pure cadmium telluride powder can be blended with an elemental tellurium powder to create a tellurium-rich powder to increase the grain size of the resulting cadmium telluride film, thereby improving carrier mobility, as well as resulting in a rougher surface morphology for the cadmium telluride film. Alternatively, a substantially pure cadmium telluride powder can be blended with an elemental cadmium powder, resulting in a cadmium-rich film with smaller grain size and a smoother surface. Roughness of cadmium telluride films has a strong impact on back contact metal adhesion. Higher surface roughness can improve the adhesion of the metal stack to the cadmium telluride film, thereby reducing the risk of de-lamination and module failure.

Electron Beam Scattered Diffraction (EBSD) and plane-view Scanning Electron Microscopy (SEM) can be used to study the impact of off-stoichiometric cadmium telluride powders on the orientation and grain size of the resulting cadmium telluride films. Cadmium telluride films that are 1 atomic % cadmium-rich can have a smaller grain size (e.g., less than about 1 μm) compared to control samples, whereas tellurium-rich films can have a larger grain size (e.g., greater than about 1 μm). The change in stoichiometry can result in a change of in-plane orientation. For example, films with a 1:1 cadmium-to-tellurium ratio can be generally oriented in the [001] direction, while the orientation can be [111] for the cadmium-rich powder, and [101] for the tellurium-rich powder.

In one aspect, a method of manufacturing a photovoltaic device can include forming a vapor comprising a first and second component and depositing the vapor as a semiconductor layer adjacent to a substrate. The vapor can be rich in one of the two components, such as the first component. The step of forming a vapor can include vaporizing a binary semiconductor source having a first and second component, wherein the binary semiconductor source is rich in the first component. The binary semiconductor source can include a binary semiconductor powder. The binary semiconductor source can be formed by adding an additional amount of the first component to a substantially pure binary semiconductor source to make the source rich in the first component prior to the step of vaporizing the binary semiconductor source. The additional amount of the first component can be added to the substantially pure binary semiconductor source by doping the substantially pure binary semiconductor source with the first component prior to the step of vaporizing a doped binary semiconductor source.

The step of forming the binary semiconductor source rich in the first component can include blending a substantially pure cadmium telluride powder with an elemental tellurium powder to form a tellurium-rich cadmium telluride powder. The substantially pure cadmium telluride powder can have a cadmium-to-tellurium ratio of 1:1. The step of forming the binary semiconductor source rich in the first component can include blending a substantially pure cadmium telluride powder with an elemental cadmium powder to form a cadmium-rich cadmium telluride powder. The substantially pure cadmium telluride powder can have a cadmium-to-tellurium ratio of 1:1. The tellurium-rich cadmium telluride powder can be between about 0.005 atomic % and about 20 atomic % tellurium-rich. The tellurium-rich cadmium telluride powder can be between about 0.2 atomic % and about 2 atomic % tellurium-rich. The cadmium-rich cadmium telluride powder can be between about 0.005 atomic % and about 20 atomic % cadmium-rich. The cadmium-rich cadmium telluride powder can be between about 0.2 atomic % and about 2 atomic % cadmium-rich.

The method can include forming a transparent conductive oxide layer adjacent to the substrate before depositing the vapor to form the semiconductor layer. The method can include forming a cadmium sulfide layer adjacent to the transparent conductive oxide layer before depositing the vapor to form the semiconductor layer. The method can include forming a barrier layer adjacent to the substrate before forming the transparent conductive oxide layer. The method can include forming a buffer layer adjacent to the transparent conductive oxide layer before depositing the vapor to form the semiconductor layer. The method can include forming a back contact metal adjacent to the semiconductor layer after depositing the vapor to form the semiconductor layer. The method can include annealing the substrate after forming the transparent conductive oxide layer and forming the cadmium sulfide layer on the annealed transparent conductive oxide stack, before depositing the vapor to form the semiconductor layer adjacent to the cadmium sulfide layer.

In one aspect, a method of controlling the properties of a binary semiconductor layer can include the steps of vaporizing a binary semiconductor source having a first and second component. The binary semiconductor source can be rich in one of the two components, for example, the first component. The method can include depositing the vapor as a semiconductor layer adjacent to a substrate. The semiconductor layer can have a crystal orientation different from the orientation of a second semiconductor layer formed by vaporizing a substantially pure binary semiconductor source. The substantially pure binary semiconductor source can include a substantially pure cadmium telluride powder having a cadmium-to-tellurium ratio of 1:1. The semiconductor layer has an average grain size smaller than the average grain size of a second semiconductor layer formed by vaporizing a substantially pure binary semiconductor source. The substantially pure binary semiconductor source can include a substantially pure cadmium telluride powder having a cadmium-to-tellurium ratio of 1:1. The semiconductor layer has an average grain size larger than the average grain size of a second semiconductor layer formed by vaporizing a substantially pure binary semiconductor source. The substantially pure binary semiconductor source can include a substantially pure cadmium telluride powder having a cadmium-to-tellurium ratio of 1:1.

In one aspect, a photovoltaic device can include a substrate, a transparent conductive oxide layer formed adjacent to the substrate, a buffer layer adjacent to the transparent conductive oxide layer, a cadmium sulfide semiconductor window layer adjacent to the buffer layer, and a doped binary semiconductor layer adjacent to the cadmium sulfide semiconductor window layer. The doped binary semiconductor layer can have a first and second component. The doped binary semiconductor layer can be rich in one component. The photovoltaic device can include a metal back contact adjacent to the doped binary semiconductor layer.

The doped binary semiconductor layer can include a tellurium-rich cadmium telluride. The doped binary semiconductor layer can include a cadmium-rich cadmium telluride. The tellurium-rich cadmium telluride layer can be between about 0.005 atomic % and about 20 atomic % tellurium-rich. The cadmium-rich cadmium telluride layer can be between about 0.005 atomic % and 20 atomic % cadmium-rich. The tellurium-rich cadmium telluride layer can have a root mean square roughness of between about 50 nm and about 300 nm. The back contact metal can be more adhesive to the tellurium-rich cadmium telluride than to a substantially pure cadmium telluride having a cadmium-to-tellurium ratio of 1:1. The cadmium-rich cadmium telluride layer can have a root mean square roughness of less than about 100 nm. The cadmium-rich cadmium telluride layer can have a root mean square roughness between about 20 nm and about 50 nm.

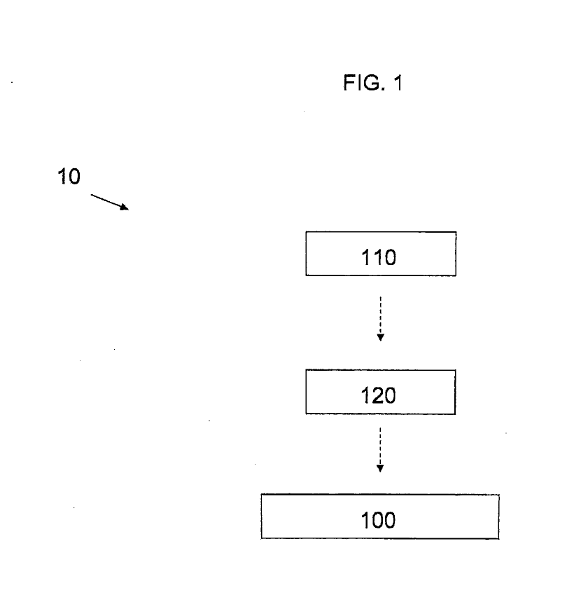

Referring to FIG. 1, a photovoltaic module 10 can include a substrate 100 with one or more semiconductor layers deposited thereon. Substrate 100 may include any suitable material, including, for example, a glass substrate, or it can contain a stack of one or more layers, which may also include a glass substrate. One of the layers within this stack can be a transparent conductive oxide such as tin oxide or cadmium stannate. The one or more semiconductor layers may include a cadmium telluride layer 110 on a cadmium sulfide layer 120. Cadmium sulfide layer 120 can be a semiconductor window layer formed adjacent to a transparent conductive oxide layer, which can be formed adjacent to substrate 100. Cadmium telluride layer 110 can be a semiconductor absorber layer formed adjacent to cadmium sulfide layer 120. Cadmium telluride layer 120 is a binary semiconductor layer.

Cadmium sulfide layer 120 can be formed in any suitable manner. Cadmium sulfide layer 120 can be formed from a vapor deposited as a semiconductor layer adjacent to cadmium sulfide layer 110. The vapor can be formed from by vaporizing a binary semiconductor source, which can include a first component, such as a first semiconductor (e.g., cadmium or tellurium), and a second component, such as a second semiconductor (e.g., cadmium or tellurium, and different from the first semiconductor). The vapor can be rich in one or the other components. For example, the vapor can be rich in cadmium, or rich in tellurium, compared to a vapor formed from a substantially pure semiconductor source (e.g., a source including cadmium and tellurium in a ratio of 1:1). The vapor can be rich in one component from being formed by vaporizing a binary semiconductor source rich in one of the components. A component-rich binary semiconductor source can be formed by adding an additional or extra amount of one of the components to a substantially pure binary semiconductor source. The component-rich binary semiconductor source can be between about 0.005 atomic % and about 20 atomic % rich in one component. The component-rich binary semiconductor source can be between about 0.005 atomic % and about 5 atomic % rich in one component. The component-rich binary semiconductor source can be between about 0.2 atomic % and about 2 atomic % rich in one component. The vapor can be made rich in one component by any suitable method. For example, a greater quantity of a first component than the second component can be allowed to enter a deposition chamber, resulting in a vapor that is rich in first component.

In some embodiments, cadmium telluride layer 110 may be formed using a modified cadmium telluride powder that is cadmium- or tellurium-rich. The modified cadmium telluride powder can be obtained by doping a substantially pure cadmium telluride powder having a nominal 1:1 ratio of cadmium-to-tellurium. The modified cadmium telluride powder may be off-stoichiometry by any suitable atomic % of cadmium or tellurium. For example, the modified cadmium telluride powder may be either cadmium- or tellurium-rich by between about 0.005 atomic % and about 20 atomic %. The modified cadmium telluride powder may be either cadmium- or tellurium-rich by between about 0.005 atomic % and about 20 atomic %. The modified cadmium telluride powder may be either cadmium- or tellurium-rich by between about 0.005 atomic % and about 20 atomic %. The modified cadmium telluride powder can be 1 atomic % cadmium-rich or tellurium-rich cadmium telluride. The resulting powder can be deposited using any suitable means. For example, the modified cadmium telluride powder can be continuously fed into a ceramic distributor and vaporized, resulting in a shift in the concentration of growth ambient compared to vaporizing pure cadmium telluride powder. The modified powder and vapor may be off-stoichiometry to a degree greater than the resulting film.

Resulting cadmium telluride layer 110 may be off-stoichiometry by any suitable amount. For example, cadmium telluride layer 110 can be off-stoichiometry by between about 0.005 atomic % and about 20 atomic %. Cadmium telluride layer 110 can be off-stoichiometry by between about 0.005 atomic % and about 5 atomic %. Cadmium telluride layer 110 can be off-stoichiometry by between about 0.2 atomic % and about 2 atomic %. Cadmium telluride layer 110 can be off-stoichiometry to a lesser degree than the modified powder and vapor. Cadmium telluride layer 110 which is tellurium-rich can have increased grain size, increased roughness, and improved back contact metal adhesion all of which may contribute to improved device efficiency. Cadmium telluride layer 110 which is cadmium-rich may demonstrate increased smoothness and smaller grain size, which may find utility in numerous applications, including, for example, infrared detectors.

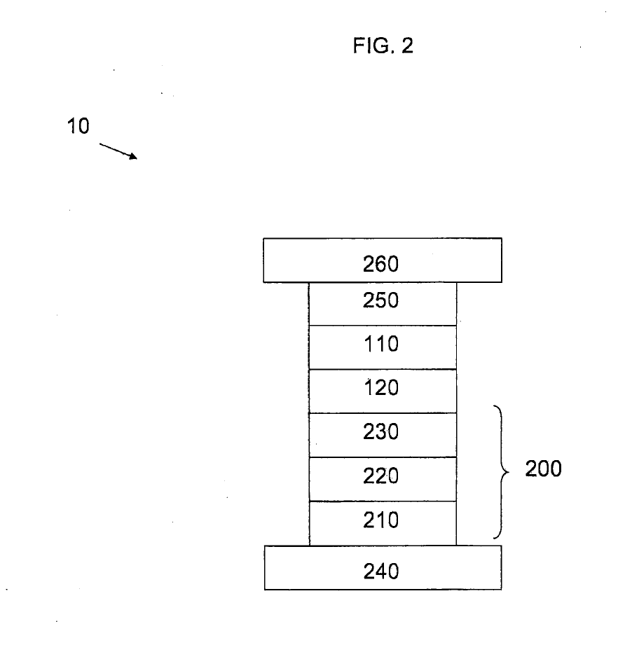

Following deposition of cadmium telluride layer 110, a back contact 250 can be deposited onto the module, followed by a back support 260, as shown in FIG. 2. Back contact 250 can include any suitable material, including metal. A tellurium-rich cadmium telluride layer 110 can improve the adhesiveness between the cadmium telluride layer and the back contact. Cadmium sulfide layer 120 and cadmium telluride layer 110 can be deposited onto a stack of layers, for example, a transparent conductive oxide stack 200, which may include a transparent conductive oxide layer 220 on a barrier layer 210, and a buffer layer 230 on transparent conductive oxide layer 220. The transparent conductive oxide stack may be deposited onto a substrate 240, which may include any suitable material, including, for example, a glass, for example, a soda-lime glass.

The embodiments described above are offered by way of illustration and example. It should be understood that the examples provided above may be altered in certain respects and still remain within the scope of the claims. It should be appreciated that, while the invention has been described with reference to the above preferred embodiments, other embodiments are within the scope of the claims.

What is claimed is:

1. A method of manufacturing a photovoltaic module, the method comprising:
forming a vapor comprising a first and second component, wherein the vapor is rich in the first component; and
depositing the vapor as a semiconductor layer adjacent to a substrate.

2. The method of claim 1, wherein the step of forming a vapor comprises vaporizing a binary semiconductor source having a first and second component, wherein the binary semiconductor source is rich in the first component.

3. The method of claim 2, wherein the binary semiconductor source comprises a binary semiconductor powder.

4. The method of claim 2, wherein the binary semiconductor source is formed by adding an additional amount of the first component to a substantially pure binary semiconductor source to make the source rich in the first component, prior to the step of vaporizing the binary semiconductor source.

5. The method of claim 4, wherein the additional amount of the first component is added to the substantially pure binary semiconductor source by doping the substantially pure binary semiconductor source with the first component, prior to the step of vaporizing a doped binary semiconductor source.

6. The method of claim 4, wherein the step of forming the binary semiconductor source rich in the first component comprises blending a substantially pure cadmium telluride powder with an elemental tellurium powder to form a tellurium-rich cadmium telluride powder, the substantially pure cadmium telluride powder having a cadmium-to-tellurium ratio of 1:1.

7. The method of claim 4, wherein the step of forming the binary semiconductor source rich in the first component comprises blending a substantially pure cadmium telluride powder with an elemental cadmium powder to form a cadmium-rich cadmium telluride powder, the substantially pure cadmium telluride powder having a cadmium-to-tellurium ratio of 1:1.

8. The method of claim 6, wherein the tellurium-rich cadmium telluride powder is between about 0.005 atomic % and about 20 atomic % tellurium-rich.

9. The method of claim 8, wherein the tellurium-rich cadmium telluride powder is between about 0.2 atomic % and about 2 atomic % tellurium-rich.

10. The method of claim 7, wherein the cadmium-rich cadmium telluride powder is between about 0.005 atomic % and about 20 atomic % cadmium-rich.

11. The method of claim 10, wherein the cadmium-rich cadmium telluride powder is between about 0.2 atomic % and about 2 atomic % cadmium-rich.

12. The method of claim 1, further comprising forming a transparent conductive oxide layer adjacent to the substrate before depositing the vapor to form the semiconductor layer.

13. The method of claim 12, further comprising forming a cadmium sulfide layer adjacent to the transparent conductive oxide layer before depositing the vapor to form the semiconductor layer.

14. The method of claim 12, further comprising forming a barrier layer adjacent to the substrate before forming the transparent conductive oxide layer.

15. The method of claim 12, further comprising forming a buffer layer adjacent to the transparent conductive oxide layer before depositing the vapor to form the semiconductor layer.

16. The method of claim 1, further comprising forming a back contact metal adjacent to the semiconductor layer after depositing the vapor to form the semiconductor layer.

17. The method of claim 13, further comprising
annealing the substrate after forming the transparent conductive oxide layer; and
forming the cadmium sulfide layer on the annealed transparent conductive oxide stack, before depositing the vapor to form the semiconductor layer adjacent to the cadmium sulfide layer.

18. A method of controlling the properties of a binary semiconductor layer, comprising:
vaporizing a binary semiconductor source having a first and second component, wherein the binary semiconductor source is rich in the first component; and
depositing the vapor as a semiconductor layer adjacent to a substrate.

19. The method of claim 18, wherein the semiconductor layer has a crystal orientation different from the orientation of a second semiconductor layer formed by vaporizing a substantially pure binary semiconductor source.

20. The method of claim 19, wherein the substantially pure binary semiconductor source comprises a substantially pure cadmium telluride powder having a cadmium-to-tellurium ratio of 1:1.

21. The method of claim 18, wherein the semiconductor layer has an average grain size smaller than the average grain size of a second semiconductor layer formed by vaporizing a substantially pure binary semiconductor source.

22. The method of claim 21, wherein the substantially pure binary semiconductor source comprises a substantially pure cadmium telluride powder having a cadmium-to-tellurium ratio of 1:1.

23. The method of claim 18, wherein the semiconductor layer has an average grain size larger than the average grain size of a second semiconductor layer formed by vaporizing a substantially pure binary semiconductor source.

24. The method of claim 21, wherein the substantially pure binary semiconductor source comprises a substantially pure cadmium telluride powder having a cadmium-to-tellurium ratio of 1:1.
